(19) United States
(12) Patent Application Publication
(10) Pub. No.: US 2026/0293575 A1
(43) Pub. Date: Sep. 24, 2026

(54) SUBSTRATE PROCESSING APPARATUS

(71) Applicant: SCREEN Holdings Co., Ltd., Kyoto (JP)

(72) Inventors: Shumpei MORI, Kyoto (JP); Mitsutoshi SASAKI, Kyoto (JP); Manabu YAMAMOTO, Kyoto (JP); Takashi IZUTA, Kyoto (JP)

(21) Appl. No.: 19/565,118

(22) Filed: Mar. 12, 2026

(30) Foreign Application Priority Data
Mar. 19, 2025 (JP) 2025-045879

(51) Int. Cl. H10P 72/00; F26B 5/00

(52) U.S. Cl. CPC H10P 72/0416; F26B 5/00

(57) ABSTRACT

A yield of a product is improved. A substrate processing apparatus includes a substrate holder, the substrate holder including a first retaining arm and a second retaining arm, the first retaining arm and the second retaining arm each including a bolt and a nut that fix a retaining body, an inner support plate, and an outer support plate thereof, the bolt being disposed, with respect to the retaining body, on a side closer to a plane with a normal direction thereof extending in a horizontal direction, the plane including a line crossing the centers of a plurality of the substrates retained by the substrate holder, the nut being disposed on a side farther from the plane with respect to the retaining body.

This Nonprovisional application claims priority under 35 U.S.C. §119 on Patent Application No. 2025-045879 filed in Japan on March 19, 2025, the entire contents of which are hereby incorporated by reference.

### TECHNICAL FIELD

The present disclosure relates to a substrate processing apparatus.

### BACKGROUND ART

Conventionally, a substrate processing apparatus is known which processes a substrate by immersing it in a processing liquid, such as a chemical liquid or a cleaning liquid, stored in a processing tank, and then performs a drying process to dry the substrate. Such a substrate processing apparatus includes a substrate holder configured to retain a substrate.

For example, Patent Literature 1 discloses a substrate processing apparatus including a substrate retaining mechanism movable between a "processing position" corresponding to a position that is inside an inner tank storing a processing liquid and a "drying position" corresponding to a position that is above the inner tank and inside a chamber. The substrate retaining mechanism includes a center guide, a first side guide, and a second side guide that constitute a substrate retaining guide for retaining a substrate. The guides have base members. To the base members, contact plates with which a substrate is to be brought into contact are attached with use of screws.

In addition, Patent Literature 2 discloses a substrate processing apparatus including a substrate holder. The substrate holder disclosed in Patent Literature 2 includes bar-shaped retaining frames and strip-shaped retaining pieces that retain a substrate. The strip-shaped retaining pieces are attached to the bar-shaped retaining frames with use of bolts and nuts.

### Citation List

### Patent Literature

### Patent Literature 1

Japanese Patent Application Publication Tokukai No. 2007-19238

### Patent Literature 2

Japanese Patent Application Publication Tokukai No. 2009-141257

### SUMMARY OF INVENTION

### Technical Problem

It has been known that, on a substrate that has undergone a drying process, peculiar particles adhere to the vicinity of a portion supported by a support plate of the substrate holder. With recent advances in the miniaturization of semiconductor devices, the edge exclusion width has been decreasing. Under these circumstances, there has been a need to reduce the occurrence of the peculiar particles adhering to the vicinity of the portion of the substrate supported by the support plate, because there is a risk that these particles directly affect yields of products.

It is an object of an aspect of the present disclosure to improve a yield of a product.

### Solution to Problem

In order to solve the foregoing problem, a substrate processing apparatus in accordance with the present disclosure is a substrate processing apparatus configured to carry out a predetermined process on a substrate, the substrate processing apparatus including: a processing tank storing a processing liquid; a substrate holder configured to support an outer peripheral edge portion of the substrate and retain a plurality of the substrates so that the plurality of the substrates are arranged in a normal direction of a substrate surface and are each in an upright orientation; and a substrate raising and lowering motor configured to raise and lower the substrate holder between a first position where the substrate is immersed in the processing liquid inside the processing tank and a second position where the substrate is located outside the processing tank, wherein the substrate holder is provided with at least a first retaining arm, a second retaining arm, and a fixation arm retaining the first retaining arm and the second retaining arm, with respect to a plane with a normal direction thereof extending in a horizontal direction, the plane including a line crossing centers of the plurality of the substrates retained by the substrate holder, the first retaining arm is disposed on one side of the plane, and the second retaining arm is disposed on the other side of the plane, the first retaining arm and the second retaining arm each include a retaining body having a bar shape and a side surface on which a fixation hole is formed, an inner support plate disposed on a side surface of the retaining body which side surface is closer to the plane and having a side surface on which a fixation hole is formed, an outer support plate disposed on a side surface of the retaining body which side surface is farther from the plane and having a side surface on which a fixation hole is formed, and a bolt and a nut that fix the retaining body, the inner support plate, and the outer support plate through the fixation holes, the bolt is disposed on a side closer to the plane with respect to the retaining body, and the nut is disposed on a side farther from the plane with respect to the retaining body.

### Advantageous Effects of Invention

According to an aspect of the present disclosure, it is possible to improve a yield of a product.

### BRIEF DESCRIPTION OF DRAWINGS

FIG. 1 is a view schematically illustrating one example of a schematic configuration of a substrate processing apparatus.

FIG. 2 is a block diagram illustrating a configuration of the substrate processing apparatus.

FIG. 3 is a perspective view schematically illustrating a configuration of a lifter.

FIG. 4 is a front view schematically illustrating the lifter as viewed from the front.

FIG. 5 is a front view schematically illustrating a first retaining arm included in the lifter as viewed from the front.

FIG. 6 is a front view schematically illustrating a third retaining arm included in the lifter as viewed from the front.

FIG. 7 is a view for explaining peculiar particles adhering to a substrate.

### DESCRIPTION OF EMBODIMENTS

### Embodiment 1

The following description will discuss an embodiment of the present disclosure in detail.

### Overview of substrate processing apparatus

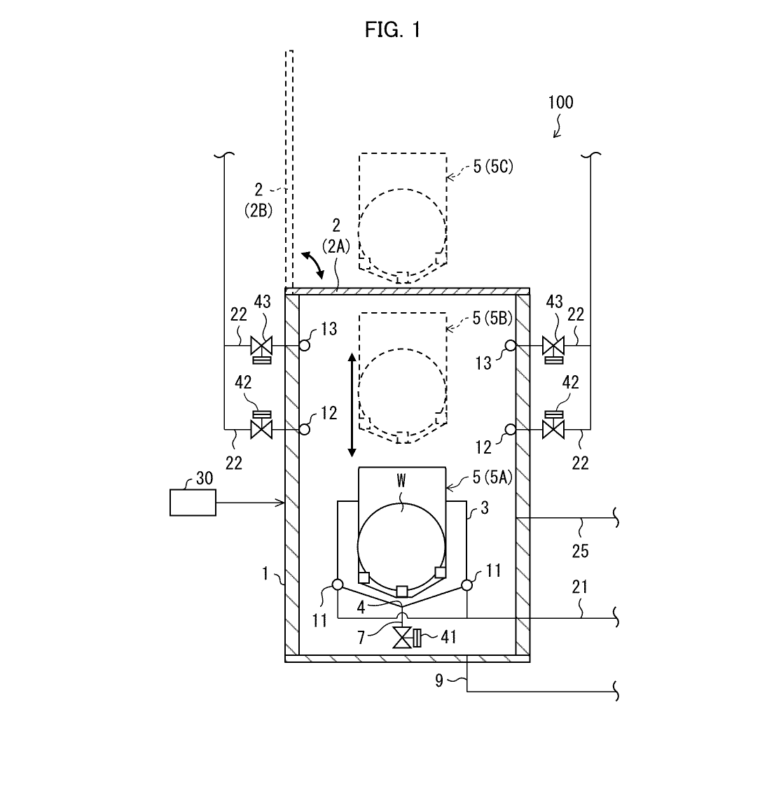

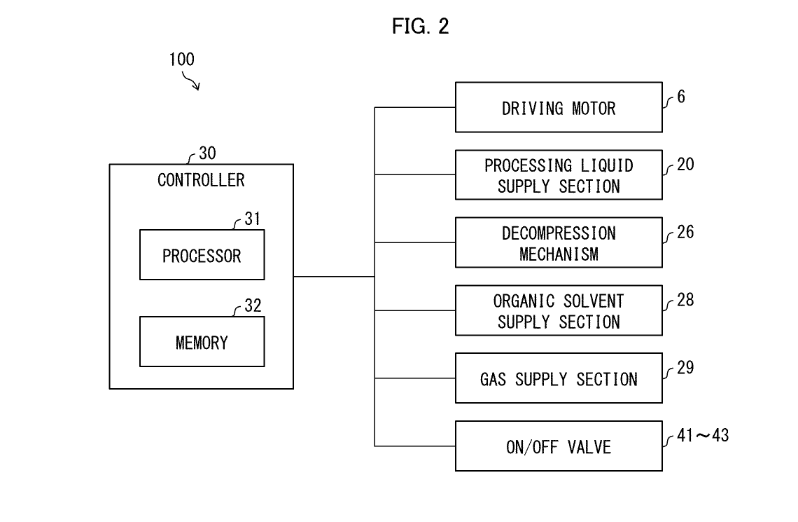

With reference to FIGS. 1 and 2, the following will describe an example of a schematic configuration of a substrate processing apparatus 100. FIG. 1 is a view schematically illustrating one example of a schematic configuration of the substrate processing apparatus 100. FIG. 2 is a block diagram illustrating a configuration of the substrate processing apparatus 100. The substrate processing apparatus 100 is an apparatus configured to carry out a predetermined process on a substrate. The substrate processing apparatus 100 carries out various processes on a substrate W with use of a processing liquid. The substrate W is, for example, a semiconductor substrate, such as a silicon wafer. The substrate processing apparatus 100 includes a processing tank 3, a lifter 5, and a driving motor 6 (see FIG. 2).

As illustrated in FIG. 1, in the present embodiment, the substrate processing apparatus 100 includes a chamber 1 accommodating the processing tank 3. An opening/closing lid 2 that opens and closes an opening formed in an upper portion of the chamber 1 is provided in an upper portion of the chamber 1. The opening/closing lid 2 is movable between a closing position 2A where the opening formed in the upper portion of the chamber 1 is closed and an opening position 2B where the opening is opened.

The processing tank 3 stores a processing liquid. The processing liquid is not particularly limited, and examples thereof include a chemical liquid and pure water. Examples of the pure water include ultrapure water (such as de-ionized water (DIW)). Examples of the chemical liquid include an ammonia-hydrogen peroxide mixture (SC-1), a hydrochloric acid-hydrogen peroxide mixture (SC-2), hydrogen fluoride (HF), isopropyl alcohol (IPA), and tetramethylammonium hydroxide (TMAH).

The processing tank 3 is provided with nozzles 11 connected to a processing liquid supply pipe 21. Each of the nozzles 11 supplies a processing liquid to the processing tank 3. More specifically, the processing liquid is supplied to the nozzle 11 from a processing liquid supply section 20 (see FIG. 2) via the processing liquid supply pipe 21. In the processing liquid stored in the processing tank 3, the substrate W raised and lowered by the lifter 5 is to be immersed.

At a lower portion of the processing tank 3, a drainage port 4 for draining the processing liquid inside the processing tank 3 to the outside of the processing tank 3 is formed. The drainage port 4 is connected to a drainage pipe 7 provided with an on/off valve 41. The processing liquid inside the processing tank 3 is drained to the bottom portion of the chamber 1 via the drainage pipe 7 when the on/off valve 41 is in an opened state, and is not drained to the bottom portion of the chamber 1 via the drainage pipe 7 when the on/off valve 41 is in a closed state. A liquid drainage pipe 9 is connected to the bottom portion of the chamber 1. The liquid accumulated at a bottom portion of the chamber 1 is drained to the outside of the chamber 1 via the liquid drainage pipe 9 when an unillustrated on/off valve is in an opened state.

The lifter 5 supports an outer peripheral edge portion of the substrate W and retains a plurality of substrates W so that the substrates W are arranged in a normal direction of a substrate surface and are each in an upright orientation. The lifter 5 is one example of a substrate holder. The lifter 5 is raised and lowered with respect to the chamber 1 through a driving force from the driving motor 6.

The lifter 5 is movable to a first position 5A, a second position 5B, and a third position 5C. The first position 5A is a position where the substrate W supported by the lifter 5 is immersed in the processing liquid inside the processing tank 3. The second position 5B is located above the first position 5A, and is a position where the substrate W supported by the lifter 5 is pulled out of the processing liquid inside the processing tank 3. The third position 5C is located above the second position 5B. In the present embodiment, the second position 5B is a position where the substrate W supported by the lifter 5 is placed inside the chamber 1. The second position 5B is located inside the chamber 1 and above the first position 5A. The third position 5C is a position where the substrate W supported by the lifter 5 is located outside the chamber 1.

An exhaust pipe 25 is connected to the chamber 1. The exhaust pipe 25 is connected to a depressurization mechanism 26 (see FIG. 2) that reduces the pressure inside the chamber 1.

The chamber 1 is provided with nozzles 12 and nozzles 13. The nozzles 12 and the nozzles 13 supply organic solvent vapor or inert gas into the chamber 1. The nozzles 12 and the nozzles 13 discharge organic solvent vapor or inert gas inside the chamber 1. The nozzles 12 and the nozzles 13 are each provided in an upper portion of the chamber 1. The nozzles 13 are located above the nozzles 12. The nozzles 12 and the nozzles 13 are each connected to a gas supply pipe 22. An unillustrated organic solvent upstream pipe connected to a supply source of organic solvent vapor and an unillustrated inert gas upstream pipe connected to a supply source of inert gas merge with an upstream portion of the gas supply pipe 22. The organic solvent upstream pipe and the inert gas upstream pipe are each provided therein with an unillustrated flow rate control valve, and thus a mixing ratio of the organic solvent vapor and the inert gas is adjustable.

The gas supply pipe 22 is provided with on/off valves 42 and on/off valves 43. More specifically, the on/off valves 42 are provided in the gas supply pipe 22 that is connected to the nozzles 12. Organic solvent vapor or inert gas is discharged into the chamber 1 from the nozzles 12 when the on/off valves 42 are in an opened state, and the organic solvent vapor or inert gas is not discharged into the chamber 1 from the nozzles 12 when the on/off valves 42 are in a closed state. The on/off valves 43 are provided in the gas supply pipe 22 that is connected to the nozzles 13. Organic solvent vapor or inert gas is discharged into the chamber 1 from the nozzles 13 when the on/off valves 43 are in an opened state, and the organic solvent vapor or inert gas is not discharged into the chamber 1 from the nozzles 13 when the on/off valves 43 are in a closed state.

As illustrated in FIG. 2, the substrate processing apparatus 100 includes the driving motor 6. In the present embodiment, the substrate processing apparatus 100 may further include a processing liquid supply section 20, the depressurization mechanism 26, an organic solvent supply section 28, and a gas supply section 29.

The driving motor 6 is a motor configured to raise and lower the lifter 5 between the first position 5A and the second position 5B. The driving motor 6 is one example of a substrate raising and lowering motor. Further, the driving motor 6 causes the lifter 5 to move between the second position 5B and the third position 5C and between the third position 5C and the first position 5A.

The processing liquid supply section 20 supplies the processing liquid to the nozzles 11. When an unillustrated driving section is driven, the processing liquid supply section 20 supplies the processing liquid from an unillustrated tank storing the processing liquid, to the processing liquid supply pipe 21. The processing liquid supply pipe 21 is provided with an unillustrated on/off valve, and when the on/off valve is in an opened state, the processing liquid supplied from the processing liquid supply pipe 21 is discharged from the nozzles 11.

The depressurization mechanism 26 reduces the pressure inside the chamber 1. The depressurization mechanism 26 includes, for example, an unillustrated exhaust pump and an unillustrated exhaust valve. For example, the exhaust valve is provided to the exhaust pipe 25. When an exhaust pump is driven with the exhaust valve in an opened state, gas in the chamber 1 is exhausted to the outside of the chamber 1 via the exhaust pipe 25. The depressurization mechanism 26 reduces the pressure in the chamber 1 by exhausting the gas in the chamber 1 via the exhaust pipe 25.

The organic solvent supply section 28 supplies organic solvent vapor into the chamber 1 via the gas supply pipe 22. When the lifter 5 is caused to move to the second position 5B, the organic solvent supply section 28 supplies organic solvent vapor from the nozzles 12 or the nozzles 13 to a space where the plurality of substrates W retained by the lifter 5 are disposed. The supply of the organic solvent vapor may be started after the lifter 5 has arrived at the second position 5B. However, the supply of the organic solvent vapor is preferably started after the lifter 5 has started moving from the first position 5A to the second position 5B and before the lifter 5 arrives at the second position 5B. For example, in response to the start of movement of the lifter 5 from the first position 5A, the supply of the organic solvent vapor is started.

The organic solvent supply section 28 includes, for example, an unillustrated organic solvent tank, an unillustrated organic solvent vapor supply pipe, and an unillustrated vapor on/off valve. The organic solvent tank is a tank that stores an organic solvent and generates vapor of the organic solvent. The organic solvent vapor supply pipe is connected to the gas supply pipe 22. The vapor on/off valve is provided to the organic solvent vapor supply pipe. When the vapor on/off valve is in an opened state, the organic solvent vapor is supplied to the gas supply pipe 22 from the organic solvent vapor supply pipe. Examples of the organic solvent supplied from the organic solvent supply section 28 include a liquid containing at least one of isopropyl alcohol (IPA), hydrofluoroether (HFE), methanol, ethanol, acetone, and Trans-1,2-dichloroethylene.

For example, reduction of the pressure inside the chamber 1 by the depressurization mechanism 26 when the on/off valves 42 and/or the on/off valves 43 are in an opened state allows the organic solvent vapor generated in the organic solvent tank to be supplied to the organic solvent vapor supply pipe and the gas supply pipe 22. The nozzles 12 and/or the nozzles 13 discharge the organic solvent vapor supplied via the gas supply pipe 22, into the chamber 1.

The gas supply section 29 supplies inert gas into the chamber 1 via the gas supply pipe 22. When the lifter 5 is caused to move from the first position 5A to the second position 5B, the gas supply section 29 supplies, after the organic solvent vapor has been supplied, inert gas as a drying gas to a space where the plurality of substrates W retained by the lifter 5 are disposed. For example, when an unillustrated driving section is driven, the gas supply section 29 supplies inert gas to the gas supply pipe 22 from an unillustrated inert gas tank storing the inert gas. The gas supply section 29 may include a gas on/off valve provided to an unillustrated inert gas supply pipe connected to the gas supply pipe 22. When the gas on/off valve is in an opened state, the inert gas is supplied to the gas supply pipe 22 from the inert gas supply pipe. Examples of the inert gas supplied from the gas supply section 29 include nitrogen gas (N₂) and argon gas (Ar).

For example, driving of the gas supply section 29 when the on/off valves 42 and/or the on/off valves 43 are in an opened state allows the inert gas stored in the inert gas tank to be supplied to the inert gas supply pipe and the gas supply pipe 22. The nozzles 12 and/or the nozzles 13 discharge the inert gas supplied via the gas supply pipe 22, into the chamber 1.

The substrate processing apparatus 100 may include a controller 30. The controller 30 controls the sections included in the substrate processing apparatus 100. As illustrated in FIG. 2, the controller 30 controls the driving motor 6, the processing liquid supply section 20, the depressurization mechanism 26, the organic solvent supply section 28, the gas supply section 29, and the on/off valves 41 to 43.

The controller 30 includes a processor 31 and a memory 32. The processor 31 carries out various processes in cooperation with the memory 32. The memory 32 stores information indicating control operations of the processor 31. For example, the processor 31 carries out various processes described later in accordance with a program stored in the memory 32 and serving as information indicating the control operations of the processor 31. The processor 31 includes, for example, a central processing unit (CPU), a digital signal processor (DSP), a graphic processing unit (GPU), and a micro processing unit (MPU). The memory 32 includes, for example, a read only memory (ROM), a random access memory (RAM), a flash memory, and a hard disk drive (HDD).

### Configuration of lifter

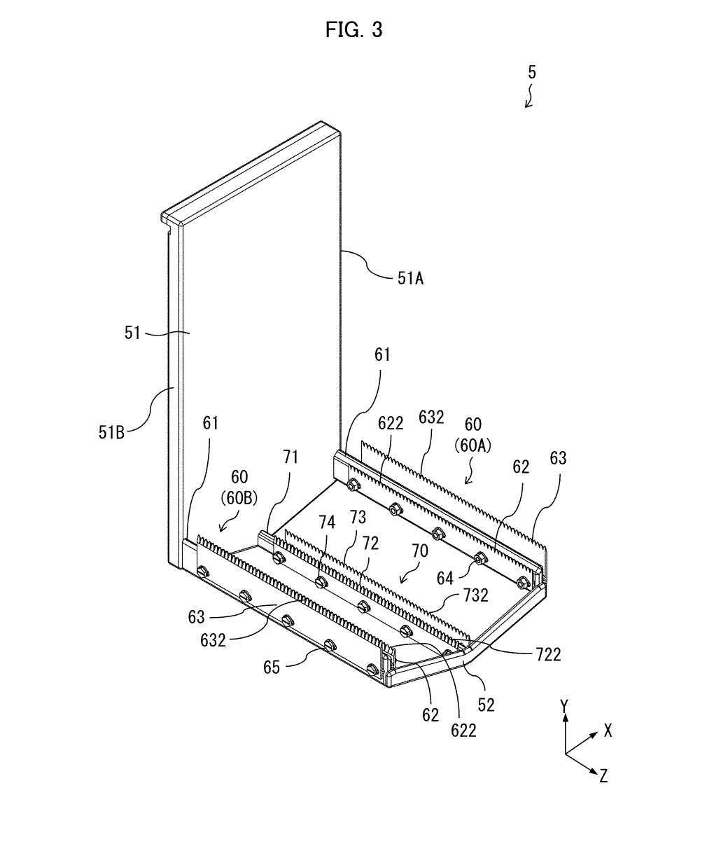

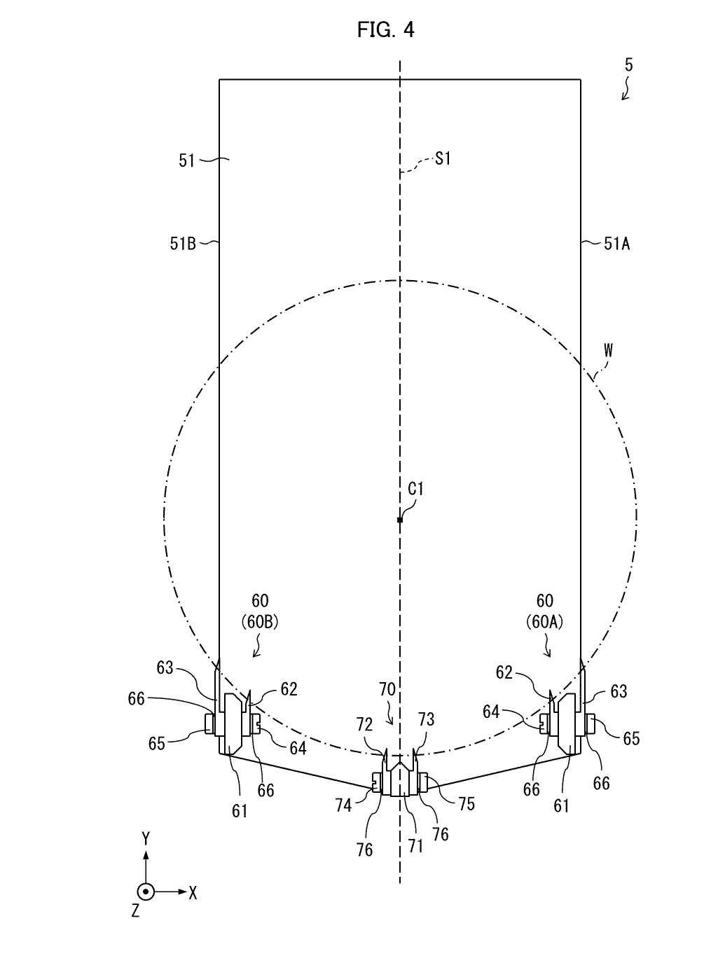

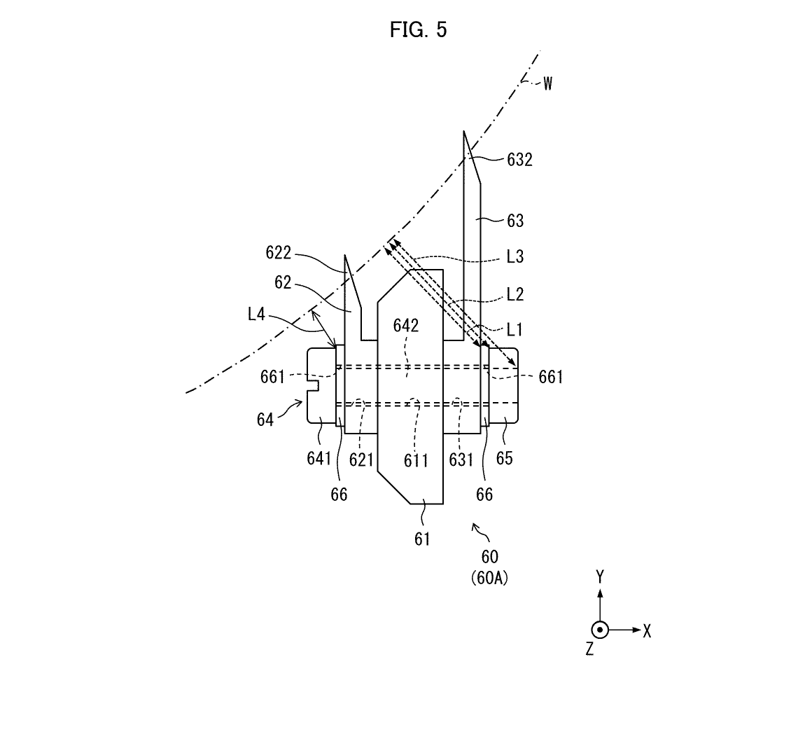

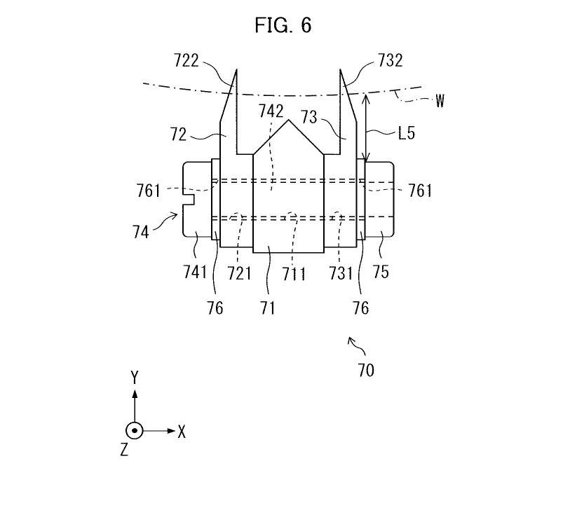

Next, with reference to FIGS. 3 to 6, the following will describe a configuration of the lifter 5 in detail. FIG. 3 is a perspective view schematically illustrating a configuration of the lifter 5. FIG. 4 is a front view schematically illustrating the lifter 5 as viewed from the front. FIG. 5 is a front view schematically illustrating a first retaining arm 60A included in the lifter 5 as viewed from the front. FIG. 6 is a front view schematically illustrating a third retaining arm 70 included in the lifter 5 as viewed from the front. Note that, in the following description, an XYZ coordinate system is defined as illustrated in, for example, FIG. 3. The X-axis direction is a horizontal direction. The Y-axis direction is the vertical direction. A Y-axis positive direction is an upward direction, and a Y-axis negative direction is a downward direction. The Z-axis direction is a horizontal direction, and is orthogonal to the X-axis direction. The XZ plane is a horizontal plane.

As illustrated in FIGS. 3 and 4, the lifter 5 is provided with at least a fixation arm 51, the first retaining arm 60A, and a second retaining arm 60B. In the present embodiment, the lifter 5 further includes a coupling arm 52 and the third retaining arm 70.

The fixation arm 51 retains the first retaining arm 60A and the second retaining arm 60B. In the present embodiment, the fixation arm 51 retains the third retaining arm 70. The fixation arm 51 is a rectangular member extending in the Y-axis direction. More specifically, the fixation arm 51 is a plate-shaped member having a substantially rectangular parallelepiped shape with its lengthwise direction extending in the Y-axis direction and with its widthwise direction extending in the X-axis direction, and having a thickness in the Z-axis direction. When a driving force from the driving motor 6 is applied to the lifter 5, the fixation arm 51 moves in an up-and-down direction. In accordance with movement of the fixation arm 51 in an up-and-down direction, the first retaining arm 60A, the second retaining arm 60B, and the third retaining arm 70 that are retained by the fixation arm 51 move in the up-and-down direction.

Here, in FIG. 4, the center C1 and an imaginary plane S1 are illustrated. In addition, in FIG. 4, an outer peripheral edge portion of the substrate W retained by the lifter 5 is illustrated by a dotted-and-dashed line. The center C1 indicates the centers of the plurality of substrates W retained by the lifter 5. The plane S1 is a plane with a normal direction thereof extending in a horizontal direction, the plane including a line crossing the center C1. The plane S1 is located in a center position of the fixation arm 51 in the X-axis direction. In the present embodiment, the normal direction of the plane S1 is the X-axis direction, and the plane S1 is a YZ plane. Of both the end portions of the fixation arm 51 in the X-axis direction, one end portion is referred to as a first end portion 51A. Of both the end portions of the fixation arm 51 in the X-axis direction, the end portion located opposite from the first end portion 51A is referred to as a second end portion 51B. In the present embodiment, the plane S1 is located in a center position between the first end portion 51A and the second end portion 51B in the X-axis direction.

The coupling arm 52 is a member coupling the first retaining arm 60A, the second retaining arm 60B, and the third retaining arm 70. The coupling arm 52 is a member extending in the X-axis direction, that is, with its lengthwise direction extending in the X-axis direction. The coupling arm 52 has a shape such that its center portion in the X-axis direction is recessed. The coupling arm 52 is a member having a V shape when viewed from the Z-axis direction. In the coupling arm 52, a position corresponding to the plane S1 constitutes the lowermost position.

The first retaining arm 60A and the second retaining arm 60B retain substrates W. With respect to the plane S1, the first retaining arm 60A is disposed on one side of the plane S1, and the second retaining arm 60B is disposed on the other side of the plane S1. That is, in the X-axis direction, the first retaining arm 60A is located on a first end portion 51A side relative to the plane S1, and the second retaining arm 60B is located on a second end portion 51B side relative to the plane S1.

In the present embodiment, the first retaining arm 60A is provided at the first end portion 51A of the fixation arm 51, and the second retaining arm 60B is provided at the second end portion 51B of the fixation arm 51. In the X-axis direction, the first retaining arm 60A is located on a first end portion 51A side with respect to the third retaining arm 70, and the second retaining arm 60B is located on a second end portion 51B side with respect to the third retaining arm 70. Note that in the present specification, in a case where the descriptions are given without distinguishing between the first retaining arm 60A and the second retaining arm 60B, they are each referred to simply as "retaining arm 60".

### Configuration of retaining arm

Next, with reference to FIGS. 3 to 5, the following will describe a configuration of the retaining arm 60 in detail. FIG. 5 illustrates a configuration of the first retaining arm 60A. The second retaining arm 60B has the same configuration as that of the first retaining arm 60A. As illustrated in FIG. 5, the retaining arm 60 includes a retaining body 61, an inner support plate 62, an outer support plate 63, bolts 64, and nuts 65.

The retaining body 61 is a bar-shaped member and has a side surface on which fixation holes 611 are formed. Each of the fixation hole 611 is a through hole penetrating through the retaining body 61 in the X-axis direction. Into the fixation hole 611, a leg portion 642 of the bolt 64 is inserted. The retaining body 61 is located, in the X-axis direction, between the inner support plate 62 and the outer support plate 63.

As illustrated in FIG. 3, the retaining body 61 is a bar-shaped member with its lengthwise direction extending in the Z-axis direction. One end portion of the retaining body 61 in the Z-axis direction is fixed to a lower portion of the fixation arm 51, and the other end portion of the retaining body 61 in the Z-axis direction is fixed to the coupling arm 52. In the present embodiment, the retaining body 61 of the first retaining arm 60A is located adjacent to the first end portion 51A of the fixation arm 51 and is fixed to a lower portion of the fixation arm 51. Further, the retaining body 61 of the second retaining arm 60B is located adjacent to the second end portion 51B of the fixation arm 51 and is fixed to a lower portion of the fixation arm 51.

As illustrated in FIG. 4, the inner support plate 62 is disposed on a side surface of the retaining body 61 which is closer to the plane S1. That is, the inner support plate 62 is located, in the X-axis direction, on the plane S1 side relative to the retaining body 61. The inner support plate 62 is fixed to the retaining body 61 by the bolts 64 and the nuts 65 while being spaced apart from the fixation arm 51 and the coupling arm 52.

As illustrated in FIG. 5, the inner support plate 62 has a side surface on which fixation holes 621 are formed. Each of the fixation holes 621 is a through hole penetrating through the inner support plate 62 in the X-axis direction. The fixation hole 621 is a hole into which the leg portion 642 of the bolt 64 is inserted. The end portion of the inner support plate 62 in the Y-axis positive direction is provided with a groove portion 622 composed of a plurality of grooves arranged in the Z-axis direction. The groove portion 622 has a comb shape. The substrate W is fitted with each groove of the groove portion 622.

As illustrated in FIG. 4, the outer support plate 63 is disposed on a side surface of the retaining body 61 which is farther from the plane S1. That is, the retaining body 61 is located, in the X-axis direction, on the plane S1 side relative to the outer support plate 63. The outer support plate 63 is fixed to the retaining body 61 by the bolts 64 and the nuts 65 while being spaced apart from the fixation arm 51 and the coupling arm 52.

As illustrated in FIG. 5, the outer support plate 63 has a side surface on which fixation holes 631 are formed. Each of the fixation holes 631 is a through hole penetrating through the outer support plate 63 in the X-axis direction. The fixation hole 631 is a hole into which a leg portion 642 of the bolt 64 is inserted. The end portion of the outer support plate 63 which is located in the Y-axis positive direction is provided with a groove portion 632 composed of a plurality of grooves arranged in the Z-axis direction. The groove portion 632 has a comb shape. The substrate W is fitted with each groove of the groove portion 632.

The outer support plate 63 is longer in the Y-axis direction than the inner support plate 62. The end portion of the outer support plate 63 on a Y-axis positive direction side is located, in a Y-axis direction, on the Y-axis positive direction side relative to the end portion of the inner support plate 62 on the Y-axis positive direction side. That is, the groove portion 632 of the outer support plate 63 is located above the groove portion 622 of the inner support plate 62 in the Y-axis direction.

The bolts 64 and the nuts 65 fix the retaining body 61, the inner support plate 62, and the outer support plate 63 through the fixation holes 611, 621, and 631. That is, the inner support plate 62 and the outer support plate 63 are each fixed to the retaining body 61 by the bolts 64 and the nuts 65.

Each of the bolts 64 is disposed on a side closer to the plane S1 with respect to the retaining body 61. That is, a head portion 641 of the bolt 64 is located, in the X-axis direction, on an inner support plate 62 side with respect to the retaining body 61. More specifically, the head portion 641 is located, in the X-axis direction, on the plane S1 side relative to the inner support plate 62.

Each of the nuts 65 is disposed on a side farther from the plane S1 with respect to the retaining body 61. That is, the nut 65 is disposed, in the X-axis direction, an outer support plate 63 side with respect to the retaining body 61. More specifically, the outer support plate 63 is disposed, in the X-axis direction, on the plane S1 side relative to the nut 65. The nut 65 engages with a thread formed on the leg portion 642 of the bolt 64.

As illustrated in FIG. 4, in the present embodiment, a shortest distance in the X-axis direction between the nut 65 of the first retaining arm 60A and the first end portion 51A of the fixation arm 51 is shorter than a shortest distance in the X-axis direction between the head portion 641 of the bolt 64 of the first retaining arm 60A and the first end portion 51A of the fixation arm 51. A shortest distance in the X-axis direction between the nut 65 of the second retaining arm 60B and the second end portion 51B of the fixation arm 51 is shorter than a shortest distance in the X-axis direction between the head portion 641 of the bolt 64 of the second retaining arm 60B and the second end portion 51B of the fixation arm 51. A shortest distance in the X-axis direction between the outer support plate 63 of the first retaining arm 60A and the first end portion 51A is shorter than a shortest distance in the X-axis direction between the inner support plate 62 of the first retaining arm 60A and the first end portion 51A. A shortest distance in the X-axis direction between the outer support plate 63 of the second retaining arm 60B and the second end portion 51B is shorter than a shortest distance in the X-axis direction between the inner support plate 62 of the second retaining arm 60B and the second end portion 51B.

The retaining arms 60 may have washers 66. The washers 66 may be disposed between the inner support plate 62 and the head portions 641 of the bolts 64. The washers 66 may be disposed between the outer support plate 63 and the nuts 65.

As illustrated in FIG. 5, a distance L1 is defined as the shortest distance from a point that is on the surface of each washer 66 which faces the outer support plate 63 and that is closest to the substrate W retained by the lifter 5, to the outer peripheral edge portion of the substrate W, the washer 66 being located between the outer support plate 63 and the nut 65. The distance L1 is preferably not less than 10 mm. A distance L2 is defined as the shortest distance from a point that is on the surface of each of the nuts 65 which is closer to the plane S1 and that is closest to the substrate W retained by the lifter 5, to the outer peripheral edge portion of the substrate W. The distance L2 is preferably not less than 10 mm. A distance L3 is defined as the shortest distance from a point that is within the screw hole of the nut 65 and that is farthest from the plane S1 and closest to the substrate W retained by the lifter 5, to the outer peripheral edge portion of the substrate W. The distance L3 is preferably not less than 10 mm.

In FIG. 5, a distance L4 is defined as the shortest distance from a point that is on a surface of the head portion 641 of each of the bolts 64 which faces the inner support plate 62 and that is closest to the substrate W retained by the lifter 5, to the outer peripheral edge portion of the substrate W. The distance L4 is the shortest distance between the gap closest to the plane S1 side among the gaps between different members of the retaining arm 60 and the substrate W retained by the lifter 5.

The following will describe the third retaining arm 70. The third retaining arm 70 retains, in a position including the plane S1, the outer peripheral edge portions at lowermost edges of the substrates W retained by the lifter 5. In the present embodiment, the third retaining arm 70 is located, in the X-axis direction, at a center position between the first end portion 51A and the second end portion 51B of the fixation arm 51. The third retaining arm 70 includes a center retaining body 71, a first center support plate 72, a second center support plate 73, center bolts 74, and center nuts 75.

The center retaining body 71 has a bar shape and has a side surface on which fixation holes 711 are formed. Each of the fixation hole 711 is a through hole penetrating through the center retaining body 71 in the X-axis direction. Into the fixation hole 711, a leg portion 742 of the center bolt 74 is inserted. The center retaining body 71 is located, in the X-axis direction, between the first center support plate 72 and the second center support plate 73. That is, the center retaining body 71 is located in a position overlapping the plane S1.

As illustrated in FIG. 3, the center retaining body 71 is a bar-shaped member with its lengthwise direction extending in the Z-axis direction. One end portion of the center retaining body 71 in the Z-axis direction is fixed to a lower portion of the fixation arm 51, and the other end portion of the center retaining body 71 in the Z-axis direction is fixed to the coupling arm 52.

As illustrated in FIG. 4, the first center support plate 72 is disposed on one side surface of the center retaining body 71. In the present embodiment, the first center support plate 72 is located, in the X-axis direction, on a side toward the second end portion 51B of the fixation arm 51 relative to the center retaining body 71. As illustrated in FIG. 6, the first center support plate 72 has a side surface on which fixation holes 721 are formed. Each of the fixation hole 721 is a through hole penetrating through the first center support plate 72 in the X-axis direction. The fixation hole 721 is a hole into which the leg portion 742 of the center bolt 74 is inserted. The first center support plate 72 is fixed to the center retaining body 71 by the center bolts 74 and the center nuts 75 while being spaced apart from the fixation arm 51 and the coupling arm 52.

As illustrated in FIG. 4, the second center support plate 73 is disposed on the other side surface of the center retaining body 71. In the present embodiment, the second center support plate 73 is located, in the X-axis direction, on a side toward the first end portion 51A of the fixation arm 51 relative to the center retaining body 71. As illustrated in FIG. 6, the second center support plate 73 has a side surface on which fixation holes 731 are formed. Each of the fixation hole 731 is a through hole penetrating through the second center support plate 73 in the X-axis direction. The fixation hole 731 is a hole into which the leg portion 742 of the center bolt 74 is inserted. The second center support plate 73 is fixed to the center retaining body 71 by the center bolts 74 and the center nuts 75 while being spaced apart from the fixation arm 51 and the coupling arm 52.

The groove portions 722 and 732 each of which is composed of a plurality of grooves arranged in the Z-axis direction are formed at respective end portions of the first center support plate 72 and the second center support plate 73 in the Y-axis positive direction. The groove portion 722 and the groove portion 732 each have a comb shape. The substrate W is fitted with each groove of the groove portion 722 and the groove portion 732. The first center support plate 72 and the second center support plate 73 have substantially the same length in the Y-axis direction. Therefore, in the Y-axis direction, the end portion of the first center support plate 72 on the Y-axis positive direction side and the end portion of the second center support plate 73 on the Y-axis positive direction side are located in substantially the same position. That is, in the Y-axis direction, the groove portion 722 of the first center support plate 72 and the groove portion 732 of the second center support plate 73 are located in substantially the same position.

The center bolts 74 and the center nuts 75 fix the center retaining body 71, the first center support plate 72, and the second center support plate 73 through the fixation holes 711, 721, and 731. That is, the first center support plate 72 and the second center support plate 73 are each attached to the center retaining body 71 by the center bolts 74 and the center nuts 75. Each of the center nuts 75 engages with a thread formed on the leg portion 742 of the center bolt 74.

In the present embodiment, each of the center bolts 74 is disposed, in the X-axis direction, on a side toward the second end portion 51B of the fixation arm 51 with respect to the center retaining body 71. That is, a head portion 741 of the center bolt 74 is located, in the X-axis direction, on a second end portion 51B side with respect to the center retaining body 71. Each of the center nuts 75 is disposed, in the X-axis direction, on a side toward the first end portion 51A of the fixation arm 51 with respect to the center retaining body 71. Note that, in the X-axis direction, the head portion 741 may be located on a first end portion 51A side with respect to the center retaining body 71, and the center nut 75 may be disposed on a second end portion 51B side with respect to the center retaining body 71.

A distance L5 is defined as the shortest distance from a point that is on the surface of the center nut 75 which is closer to the center retaining body 71 and that is closest to the substrate W retained by the lifter 5, to the outer peripheral edge portion of the substrate W. The distance L5 is preferably not less than 10 mm. The distance L5 is the shortest distance between the substrate W retained by the lifter 5 and the gap, among the gaps between different members of the third retaining arm 70, that is located closest to the plane S1 side, such a gap being considered to be a location where the processing liquid is likely to remain.

The third retaining arm 70 may have center washers 76. The center washers 76 may be disposed between the first center support plate 72 and the head portions 741 of the center bolts 74 and/or between the second center support plate 73 and the center nuts 75.

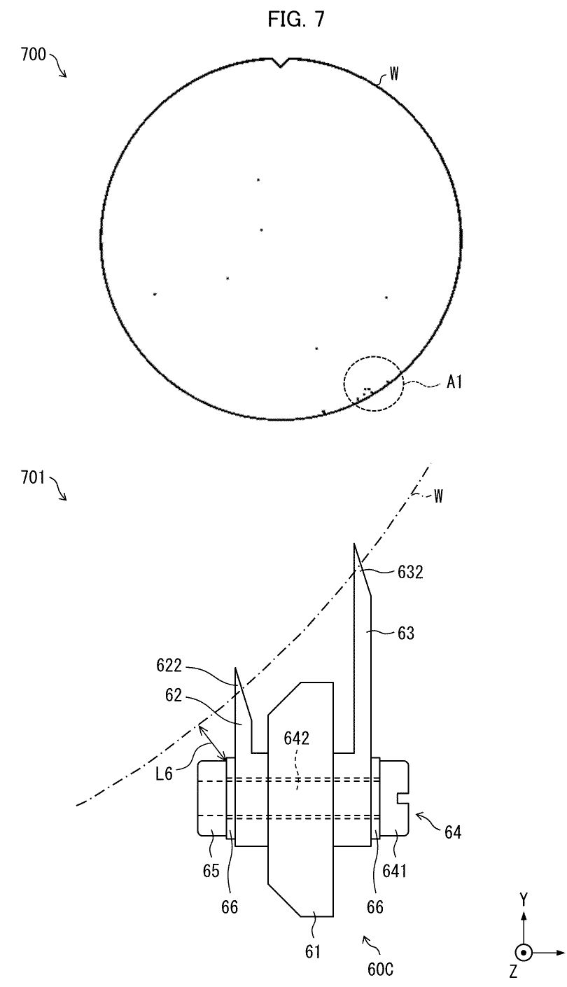

Here, with reference to FIG. 7, the following will describe peculiar particles adhering to a substrate W. The reference numeral 700 of FIG. 7 indicates an example of the peculiar particles adhering to a substrate W. Note that this example shows a state in which the particles are detected as undesirable particles with the edge exclusion of the substrate W set to not more than 2 mm. That is, with the narrowing of the edge exclusion and the miniaturization of the structures formed on the substrate W, the acceptance criteria for the particles become stricter, and particles that were conventionally acceptable come to be detected as peculiar particles.

In the reference numeral 700, the peculiar particles adhere to the portion of the substrate W indicated by the reference sign A1. It can be seen that multiple particles adhere as a cluster to the portion indicated by the reference sign A1. The portion indicated by the reference sign A1 is located in the vicinity of a portion with which an inner support plate 62 and an outer support plate 63 of a comparative retaining arm 60C are to be brought into contact.

The reference numeral 701 of FIG. 7 indicates the configuration of the comparative retaining arm 60C with the peculiar particles adhering to the substrate W. The comparative retaining arm 60C has a configuration similar to that of the first retaining arm 60A described above. The comparative retaining arm 60C differs from the retaining arm 60 in that the positions of the bolts 64 and the nuts 65 are reversed.

The comparative retaining arm 60C has a configuration such that each of the bolts 64 is disposed on a side farther from the plane S1 with respect to the retaining body 61. That is, the head portion 641 of the bolt 64 of the comparative retaining arm 60C is located, in the X-axis direction, on an outer support plate 63 side with respect to the retaining body 61. The comparative retaining arm 60C has a configuration such that each of the nuts 65 is disposed on a side closer to the plane S1 with respect to the retaining body 61. That is, the nut 65 is attached to the bolt 64 with the washer 66 interposed therebetween, on an inner support plate 62 side with respect to the retaining body 61 in the X-axis direction. A distance L6 indicated by the reference numeral 701 is the shortest distance from the washer 66 adjacent to the nut 65 to the point closest to the substrate W retained by the lifter 5.

The present inventors considered that one cause of the adhesion of the peculiar particles to the substrate W was the processing liquid remaining in the gaps existing between different members, and in relation to this, they also thought that the positions of the bolts 64 and the nuts 65 were involved. In each of the nuts 65, an opening is formed that has a female screw to engage with a thread formed on the leg portion 642 of the bolt 64. Therefore, a gap, although it is small, exists between the bolt 64 and the nut 65. That is, a gap exists between the leg portion 642 of the bolt 64 and the opening of the nut 65. In particular, a gap is likely generated between the tip of the leg portion 642 and the opening of the nut 65. When the substrate W is immersed in the processing liquid inside the processing tank 3, the processing liquid enters the slight gap between the bolt 64 and the nut 65. The processing liquid, although in a small amount, remains in the gap between the bolt 64 and the nut 65 after the substrate W has been taken out of the processing tank 3.

It has been found that the processing liquid is likely to, in particular, adhere to or remain in a gap between the bolt 64 and the adjacent washer 66 and a gap between the nut 65 and the adjacent washer 66.

Here, the present inventors have found, through diligent study, that a larger amount of the processing liquid tends to remain in the gap between the nut 65 and the adjacent washer 66 than in the gap between the bolt 64 and the adjacent washer 66. This is presumed to be because, unlike the bolt 64, the nut 65 serves as a female screw, thereby leaving a slight groove between the main shaft of the bolt 64 and the nut 65 even after the nut 65 has been rotated to engage with the main shaft of the bolt 64, and through the groove, the processing liquid flows and is more likely to adhere.

Conventionally, no attention has been paid to these phenomena, since the amount of the above-mentioned remaining processing liquid is very small, and the difference in the amount of the processing liquid accumulated in the gap between the bolt 64 and the adjacent washer 66 and that in the gap between the nut 65 and the adjacent washer 66 is also very small. The inventors have discovered the above-described phenomena due to the recent expansion of demands for edge exclusion and the increasingly stringent tolerance for remaining particles.

According to the experiment conducted by the inventors, the processing liquid is unlikely to remain in gaps between the head portion 641 of the bolt 64 and the washer 66, between the washer 66 and the outer support plate 63, between the outer support plate 63 and the retaining body 61, and between the retaining body 61 and the inner support plate 62. The normal direction of the surface of the head portion 641 which faces the washer 66 is directed in an axial direction of the leg portion 642 (in the X-axis direction). Therefore, due to the pressure generated by tightening the nut 65 onto the bolt 64, a state is created in which there are almost no gaps between the head portion 641 and the washer 66 and between the washer 66 and the outer support plate 63, thereby making it difficult for the processing liquid to enter the gaps. Further, the retaining body 61 is subjected to a coating process. Therefore, tight contacts are achieved between the outer support plate 63 and the retaining body 61 and between the retaining body 61 and the inner support plate 62, and thus there is a low possibility that the processing liquid enters the gaps between the outer support plate 63 and the retaining body 61 and between the retaining body 61 and the inner support plate 62.

In contrast, the processing liquid is likely to enter the gap between the nut 65 and the adjacent washer 66, and the processing liquid that has entered the gap is likely to remain there. Therefore, a configuration in which such gaps are as far away as possible from the substrate W makes it possible to reduce the scattering of the processing liquid onto the substrate W.

According to the above-described configurations of the first retaining arm 60A and the second retaining arm 60B, it is possible to increase the shortest distances between the nuts 65 of the first retaining arm 60A and the second retaining arm 60B and the substrate W retained by the first retaining arm 60A and the second retaining arm 60B. Therefore, even if the processing liquid remaining in the gaps between the nuts 65 and the washers 66 of the first retaining arm 60A and the second retaining arm 60B splashes, it becomes difficult for the liquid to adhere to the substrate W retained by the lifter 5. For example, in the configuration of the conventional art illustrated in FIG. 7, the distance L6 between the gap between the nut 65 and the washer 66 and the substrate W is short. In contrast, with the configuration illustrated in FIG. 5, the distance L1 or L2 from the gap between the nut 65 and the washer 66 to the substrate W becomes much longer than the distance L6. Therefore, it is possible to reduce the risk that the processing liquid remaining between the nut 65 and the washer 66 splashes onto the substrate W, thereby making it unlikely for the peculiar particles to adhere to the substrate W. This makes it possible to improve a yield of the product.

In the comparative retaining arm 60C with the peculiar particles as indicated by the reference numeral 700 in FIG. 7 adhering to the substrate W, (i) the shortest distance from the gap between the bolt 64 and the nut 65 to the outer peripheral edge portion of the substrate W, (ii) the shortest distance from the gap between the nut 65 and the washer 66 to the outer peripheral edge portion of the substrate W, and (iii) the shortest distance from the gap between the washer 66 and the inner support plate 62 to the outer peripheral edge portion of the substrate W were all shorter than 10 mm. Furthermore, in a case where the distances L1 to L3 were each not less than 10 mm in the retaining arm 60, the frequency of adhesion of the peculiar particles to the substrate W was low. Therefore, by setting each of the distances L1 to L3 to not less than 10 mm, it is possible to make the first retaining arm 60A and the second retaining arm 60B compact while reducing the adhesion of the peculiar particles to the substrate W. This makes it possible to downsize the lifter 5.

The lifter 5 includes the third retaining arm 70, thereby making it possible to stabilize the retaining of the substrate W by the lifter 5. Further, by setting the distance L5 to not less than 10 mm, it is possible to make the third retaining arm 70 compact while preventing the adhesion of the peculiar particles to the substrate W. This makes it possible to downsize the lifter 5.

The substrate processing apparatus 100 includes the gas supply section 29, thereby making it unlikely for the peculiar particles to adhere to the substrate W that has been subjected to a drying process for drying the substrate W by the substrate processing apparatus 100. This makes it possible to improve a yield of the product.

The substrate processing apparatus 100 includes the organic solvent supply section 28, thereby allowing organic solvent vapor to be supplied to the space where the substrate W is disposed, after the substrate W that is immersed in the processing liquid is caused to move to the outside of the processing tank 3. Therefore, the processing liquid remaining on the surface of the substrate W retained by the lifter 5 located in the second position 5B is replaced with the organic solvent. This makes it possible to dry the substrate W in a shorter time.

### Other embodiments

Note that in the above-described embodiment, the lifter 5 is configured to include the single first retaining arm 60A and the single second retaining arm 60B, but is not limited to such a configuration. For example, a plurality of first retaining arms 60A may be provided between the plane S1 and the first end portion 51A of the fixation arm 51, and a plurality of second retaining arms 60B may be provided between the plane S1 and the second end portion 51B of the fixation arm 51.

With respect to gas supply in the chamber, instead of switching between the organic solvent vapor and the inert gas in the gas supply pipe 22, a configuration may be employed which includes a gas supply pipe 22A for supplying only inert gas and a gas supply pipe 22B for supplying only organic solvent vapor, in which nozzles 12A and 12B corresponding to the pipes are disposed instead of the nozzles 12, and in which nozzles 13A and 13B are similarly disposed instead of the nozzles 13.

Aspects of the present invention can also be expressed as follows:

A substrate processing apparatus in accordance with an aspect of the present disclosure is a substrate processing apparatus configured to carry out a predetermined process on a substrate, the substrate processing apparatus including: a processing tank storing a processing liquid; a substrate holder configured to support an outer peripheral edge portion of the substrate and retain a plurality of the substrates so that the plurality of the substrates are arranged in a normal direction of a substrate surface and are each in an upright orientation; and a substrate raising and lowering motor configured to raise and lower the substrate holder between a first position where the substrate is immersed in the processing liquid inside the processing tank and a second position where the substrate is located outside the processing tank, wherein the substrate holder is provided with at least a first retaining arm, a second retaining arm, and a fixation arm retaining the first retaining arm and the second retaining arm, with respect to a plane with a normal direction thereof extending in a horizontal direction, the plane including a line crossing centers of the plurality of the substrates retained by the substrate holder, the first retaining arm is disposed on one side of the plane, and the second retaining arm is disposed on the other side of the plane, the first retaining arm and the second retaining arm each include a retaining body having a bar shape and a side surface on which a fixation hole is formed, an inner support plate disposed on a side surface of the retaining body which side surface is closer to the plane and having a side surface on which a fixation hole is formed, an outer support plate disposed on a side surface of the retaining body which side surface is farther from the plane and having a side surface on which a fixation hole is formed, and a bolt and a nut that fix the retaining body, the inner support plate, and the outer support plate through the fixation holes, the bolt is disposed on a side closer to the plane with respect to the retaining body, and the nut is disposed on a side farther from the plane with respect to the retaining body.

Further, in a substrate processing apparatus in accordance with an aspect of the present disclosure, a shortest distance from a point that is on a surface of the nut which surface is closer to the plane and that is closest to the substrate retained by the substrate holder, to the outer peripheral edge portion of the substrate is not less than 10 mm.

Further, in a substrate processing apparatus in accordance with an aspect of the present disclosure, a washer is disposed between the outer support plate and the nut, and a shortest distance from a point that is on a surface of the washer which surface faces the outer support plate and that is closest to the substrate retained by the substrate holder, to the outer peripheral edge portion of the substrate is not less than 10 mm.

Further, in a substrate processing apparatus in accordance with an aspect of the present disclosure, a shortest distance from a point that is within a screw hole of the nut and that is farthest from the plane and closest to the substrate retained by the substrate holder, to the outer peripheral edge portion of the substrate is not less than 10 mm.

Further, in a substrate processing apparatus in accordance with an aspect of the present disclosure, the substrate holder further includes a third retaining arm, the third retaining arm retains, in a position including the plane, the outer peripheral edge portion at a lowermost edge of the substrate, and the third retaining arm includes a center retaining body having a bar shape and a side surface on which a fixation hole is formed, a first center support plate disposed on one side surface of the center retaining body and having a side surface on which a fixation hole is formed, a second center support plate disposed on the other side surface of the center retaining body and having a side surface on which a fixation hole is formed, and a center bolt and a center nut that fix the center retaining body, the first center support plate, and the second center support plate through the fixation holes.

Further, in a substrate processing apparatus in accordance with an aspect of the present disclosure, a shortest distance from a point that is on a surface of the center nut which surface is closer to the center retaining body and that is closest to the substrate retained by the substrate holder, to the outer peripheral edge portion of the substrate is not less than 10 mm.

Further, a substrate processing apparatus in accordance with an aspect of the present disclosure further includes a nozzle configured to, when the substrate holder is caused to move from the first position to the second position, supply organic solvent vapor to a space where the plurality of the substrates retained by the substrate holder are disposed.

Further, in a substrate processing apparatus in accordance with an aspect of the present disclosure, when the substrate holder is caused to move from the first position to the second position, the nozzle supplies, after supplying the organic solvent vapor, inert gas to the space where the plurality of the substrates retained by the substrate holder are disposed.

### REFERENCE SIGNS LIST

3 Processing tank

5 Lifter (substrate holder)

5A First position

5B Second position

6 Driving motor (substrate raising and lowering motor)

28 Organic solvent supply section

29 Gas supply section

51 Fixation arm

60A First retaining arm

60B Second retaining arm

61 Retaining body

62 Inner support plate

63 Outer support plate

64 Bolt

65 Nut

70 Third retaining arm

71 Center retaining body

72 First center support plate

73 Second center support plate

74 Center bolt

75 Center nut

76 Center washer

100 Substrate processing apparatus

C1 Center

S1 Plane

What is claimed is:

1. A substrate processing apparatus configured to carry out a predetermined process on a substrate, the substrate processing apparatus comprising:
a processing tank storing a processing liquid;
a substrate holder configured to support an outer peripheral edge portion of the substrate and retain a plurality of the substrates so that the plurality of the substrates are arranged in a normal direction of a substrate surface and are each in an upright orientation; and
a substrate raising and lowering motor configured to raise and lower the substrate holder between a first position where the substrate is immersed in the processing liquid inside the processing tank and a second position where the substrate is located outside the processing tank, wherein
the substrate holder is provided with at least a first retaining arm, a second retaining arm, and a fixation arm retaining the first retaining arm and the second retaining arm,
with respect to a plane with a normal direction thereof extending in a horizontal direction, the plane including a line crossing centers of the plurality of the substrates retained by the substrate holder, the first retaining arm is disposed on one side of the plane, and the second retaining arm is disposed on the other side of the plane,
the first retaining arm and the second retaining arm each include
a retaining body having a bar shape and a side surface on which a fixation hole is formed,
an inner support plate disposed on a side surface of the retaining body which side surface is closer to the plane and having a side surface on which a fixation hole is formed,
an outer support plate disposed on a side surface of the retaining body which side surface is farther from the plane and having a side surface on which a fixation hole is formed, and
a bolt and a nut that fix the retaining body, the inner support plate, and the outer support plate through the fixation holes,
the bolt is disposed on a side closer to the plane with respect to the retaining body, and
the nut is disposed on a side farther from the plane with respect to the retaining body.

2. The substrate processing apparatus according to claim 1, wherein a shortest distance from a point that is on a surface of the nut which surface is closer to the plane and that is closest to the substrate retained by the substrate holder, to the outer peripheral edge portion of the substrate is not less than 10 mm.

3. The substrate processing apparatus according to claim 1, wherein
a washer is disposed between the outer support plate and the nut, and
a shortest distance from a point that is on a surface of the washer which surface faces the outer support plate and that is closest to the substrate retained by the substrate holder, to the outer peripheral edge portion of the substrate is not less than 10 mm.

4. The substrate processing apparatus according to claim 1, wherein a shortest distance from a point that is within a screw hole of the nut and that is farthest from the plane and closest to the substrate retained by the substrate holder, to the outer peripheral edge portion of the substrate is not less than 10 mm.

5. The substrate processing apparatus according to claim 1, wherein
the substrate holder further includes a third retaining arm,
the third retaining arm retains, in a position including the plane, the outer peripheral edge portion at a lowermost edge of the substrate, and
the third retaining arm includes
a center retaining body having a bar shape and a side surface on which a fixation hole is formed,
a first center support plate disposed on one side surface of the center retaining body and having a side surface on which a fixation hole is formed,
a second center support plate disposed on the other side surface of the center retaining body and having a side surface on which a fixation hole is formed, and
a center bolt and a center nut that fix the center retaining body, the first center support plate, and the second center support plate through the fixation holes.

6. The substrate processing apparatus according to claim 5, wherein a shortest distance from a point that is on a surface of the center nut which surface is closer to the center retaining body and that is closest to the substrate retained by the substrate holder, to the outer peripheral edge portion of the substrate is not less than 10 mm.

7. The substrate processing apparatus according to claim 1, further comprising a nozzle configured to, when the substrate holder is caused to move from the first position to the second position, supply organic solvent vapor to a space where the plurality of the substrates retained by the substrate holder are disposed.

8. The substrate processing apparatus according to claim 7, wherein when the substrate holder is caused to move from the first position to the second position, the nozzle supplies, after supplying the organic solvent vapor, inert gas to the space where the plurality of the substrates retained by the substrate holder are disposed.
